(19) United States
(12) Patent Application Publication
(10) Pub. No.: US 2015/0035130 A1
(43) Pub. Date: Feb. 5, 2015

(54) Integrated Circuit with Stress Isolation

(71) Applicant: Texas Instruments Incorporated, Dallas, TX (US)

(72) Inventor: You Chye How, Taman Semabok Permai (MY)

(73) Assignee: Texas Instruments Incorporated, Dallas, TX (US)

(21) Appl. No.: 13/954,916

(22) Filed: Jul. 30, 2013

(51) Int. Cl. H01L 23/28; H01L 21/56

(52) U.S. Cl. CPC H01L 23/28; H01L 21/56
USPC 257/678; 438/127

(57) ABSTRACT

A packaged semiconductor device has a semiconductor substrate with circuitry formed thereon. A shield plate is mounted over a designated region of the substrate and separated from the semiconductor substrate by a separator, such that the shield plate is separated from the designated region of the substrate by a distance. Mold compound encapsulates the semiconductor substrate and the shield plate, but is prevented from touching the designated region of the substrate by the shield plate.

### FIELD OF THE INVENTION

This invention generally relates to packaging of integrated circuits, and in particular to stress-sensitive analog circuits, including microelectromechanical systems.

### BACKGROUND OF THE INVENTION

In electronics manufacturing, integrated circuit (IC) packaging is the final stage of semiconductor device fabrication, in which an IC, commonly referred to as a chip or die, of semiconducting material is encased in a supporting case that prevents physical damage and corrosion. The case, known as a “package”, supports the electrical contacts which connect the device to a circuit board.

A large percentage of the world's ICs are packaged using a hot, high pressure transfer molding process. The stress created by the flow of silica powder loaded epoxy can displace the fine bonding wires and can even distort the metallization patterns under the protective chip passivation layer. Epoxy molding compound (EMC) is a common material used in IC packaging. One of its defects is warpage. Warpage may be a serious issue for some IC encapsulation processes. To alleviate the warpage problem during encapsulation, a post mold cure process (PMC) may be used. EMC behaves like a viscoelastic material during post mold cure process; therefore, a viscoelastic model may be used to analyze stress induced by the EMC.

Wire bonding is the method of making interconnections between an IC or other semiconductor device and its packaging during semiconductor device fabrication. Although less common, wire bonding can be used to connect an IC to other electronics or to connect from one PCB to another. Wire bonding is generally considered a cost-effective and flexible interconnect technology and is used to assemble a large portion of semiconductor packages.

### BRIEF DESCRIPTION OF THE DRAWINGS

Particular embodiments in accordance with the invention will now be described, by way of example only, and with reference to the accompanying drawings:

FIG. 1 is an illustration of an integrated circuit (IC) die mounted to a leadless leadframe package (LLP) frame;

FIG. 2 is a sectional view and of the IC die of FIG. 1 illustrating a stress protection shield plate and cavity frame mounted over a critical portion of the IC;

FIGS. 3 and 4 illustrate formation of the shield plate and cavity frame of FIG. 2;

FIG. 5 illustrates placement of the cavity frame on the IC of FIG. 1;

FIG. 6 is an illustration of the IC of FIG. 1 after it has been encapsulated;

FIG. 7 illustrates another embodiment of a cavity frame; and

FIG. 8 is a flow diagram illustrating provision of stress isolation for stress sensitive circuitry.

Other features of the present embodiments will be apparent from the accompanying drawings and from the detailed description that follows.

### DETAILED DESCRIPTION OF EMBODIMENTS OF THE INVENTION

Specific embodiments of the invention will now be described in detail with reference to the accompanying figures. Like elements in the various figures are denoted by like reference numerals for consistency. In the following detailed description of embodiments of the invention, numerous specific details are set forth in order to provide a more thorough understanding of the invention. However, it will be apparent to one of ordinary skill in the art that the invention may be practiced without these specific details. In other instances, well- known features have not been described in detail to avoid unnecessarily complicating the description.

A large percentage of the world's ICs are packaged using a hot, high pressure transfer molding process, typically using an epoxy molding compound (EMC). Warpage caused by the EMC may be a serious issue for some ICs and may cause product performance drift, especially for precision analog products. Product performance drift may be induced by mold compound acting on a die surface that has circuitry that is sensitive to package stress. This mold stress problem may occur in any molded IC package that uses mold compound as a package encapsulation material.

Prior attempts to reduce package induced stress rely on a silicone base material that is deposited on the die surface, typically after wire bonding has been performed. In other examples, the silicone base material may be applied to an IC wafer prior to dividing it into separate IC dice by screen printing or spin coating, for example. This silicone material may be selected to have a low temperature coefficient of expansion modulus to reduce mold stress from directly acting on product sensitive circuit area. However, since the silicone material is in contact with the sensitive circuit area, a portion of the package induced stress may still be transferred to the sensitive circuit area.

Embodiments of the invention provide a shield that is physically separated from the sensitive circuit area on precision analog products by using a shield plate that is cut from a silicon wafer to completely avoid mold compound induced stress. Silicon wafer material may be used for the shield material because it has a similar coefficient of thermal expansion (CTE) as wafers used to produce the integrated circuit and thereby prevent any CTE induced stress to the product.

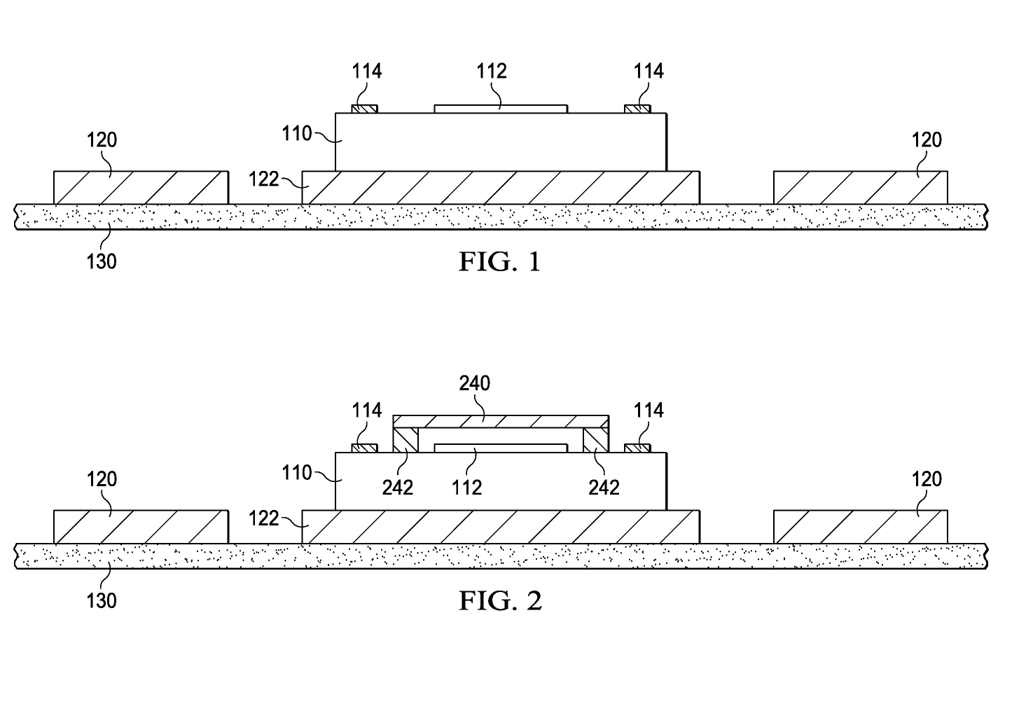

FIG. 1 is an illustration of an integrated circuit (IC) die 110 mounted to a Quad flat no-lead (QFN) frame 120,122. IC die 110 includes a set of wire bond pads 114. The QFN includes a central portion 122 that holds die 110 and a set of contact fingers 120 that may then be used to connect to a system substrate, such as a printed circuit board, for example. Lead wires (not shown) are connected between each bond pad and a corresponding lead frame contact 120. A portion 112 of die 110 may contain circuitry, such as analog circuitry for example, that may be sensitive to packaging stress.

FIG. 2 is a sectional view and of IC die 110 of FIG. 1 illustrating a stress protection shield plate 240 and cavity frame 242 mounted over a critical portion 112 of the IC. Cavity frame 242 may completely surround sensitive area 112 such that together with shield plate 240 it prevents EMC from contacting critical portion 112.

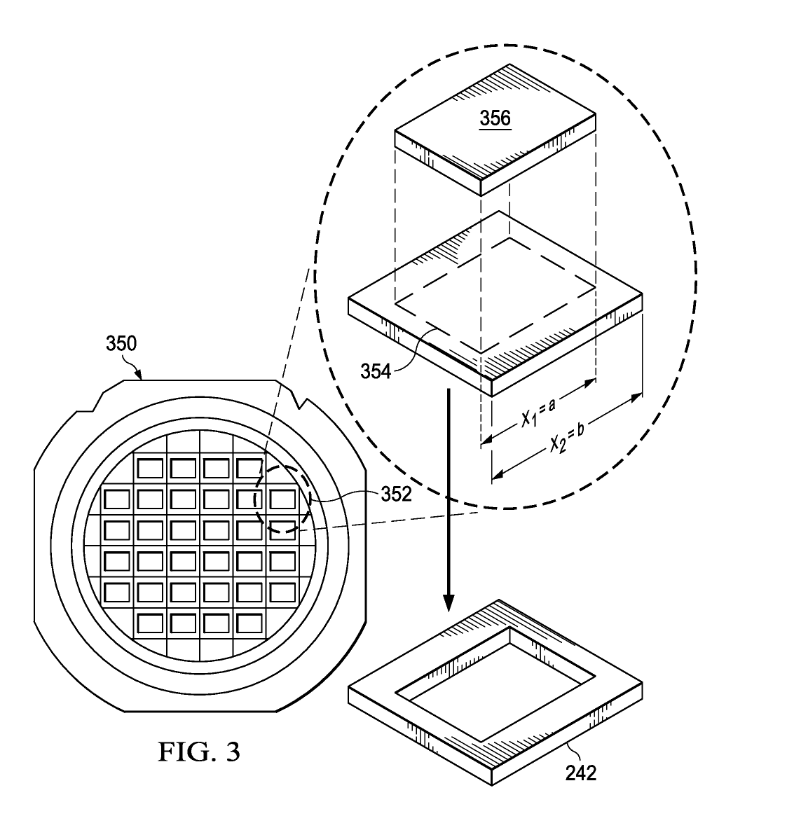

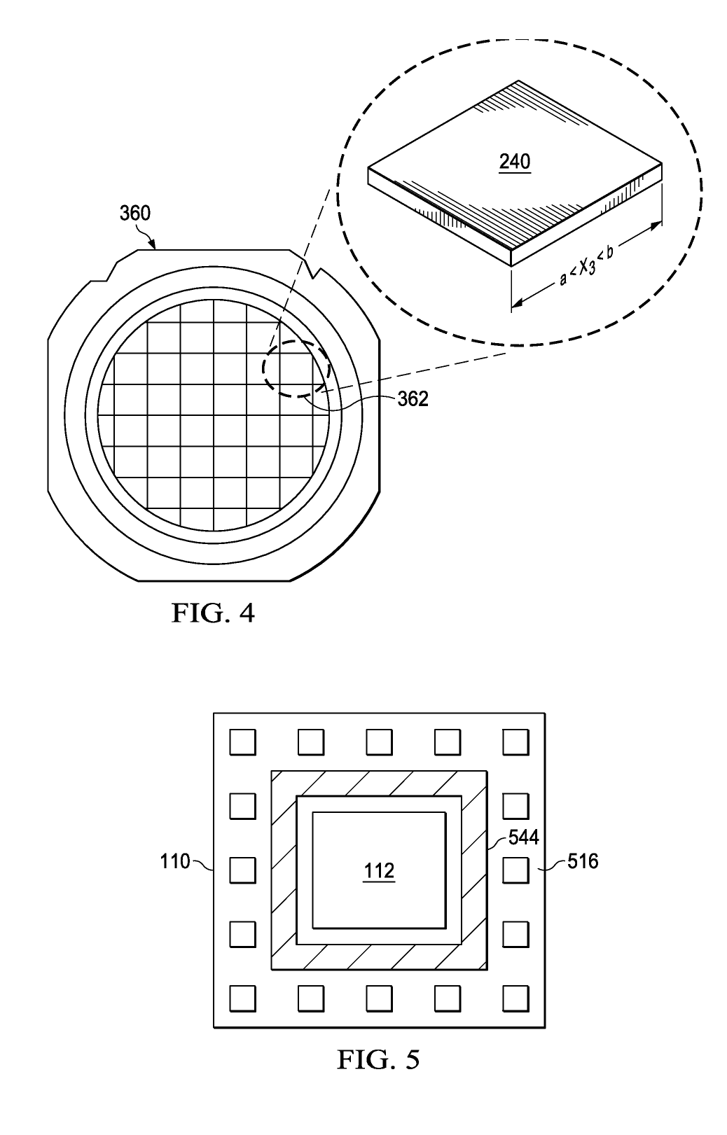

FIGS. 3 and 4 illustrate formation of shield plate 240 and cavity frame 242 of FIG. 2. In FIG. 3, a dummy silicon wafer 350 is used to form cavity frame 242. Dummy wafer 350 may be a completely unprocessed wafer or it may be a partially processed wafer that was rejected for some reason during processing, for example. Chip 352 is representative of a set of chips that may be produced from wafer 350 using a laser or mechanical saw, for example. A laser cutter may be used to cut out an interior portion 356 of each chip 352 along cut lines 354 to form cavity frame 242. Various types of known or later developed laser dicing techniques may be use, such as: laser ablation, stealth laser dicing, water jet laser, etc.

Each cavity frame 242 has an interior dimension x1=a and an exterior dimension x2=b. Here, each cavity frame is shown as being square; however, in other embodiments it may be rectangular or be some other shape, depending on the configuration of a sensitive circuit region.

In FIG. 4, a second dummy silicon wafer 360 is used to form shield plate 240. Dummy wafer 360 may be a completely unprocessed wafer or it may be a partially processed wafer that was rejected for some reason during processing, for example. Chip 362 is representative of a set of chips that may be produced from wafer 360 using a laser or mechanical saw, for example. Each shield plate 240 has an exterior dimension a<x3<b so that it will fit over cavity frame 242. Here, each shield plate is shown as being square; however, in other embodiments it may be rectangular or be some other shape, depending on the configuration of a sensitive circuit region and the shape of the corresponding cavity frame.

Cavity frame 242 and shield plate 240 may be mounted to a die attach film (DAF) that provides adhesion for mounting onto IC die 110. Other embodiments may use other known or later developed forms of adhesive material, such as silicon epoxy, etc.

Once the cavity frame and shield plate is attached to IC die 110, additional assembly processing may be performed, such as wire bond, mold, etc. In some embodiments, wire bonding may be performed prior to attaching cavity frame or shield plate, for example.

Using currently available processing machinery, the thickness of the shield plate may need to be at least 10 mils. However, thinner material may be used if an available automated handling system is able handle thinner silicon.

FIG. 5 illustrates placement of the cavity frame on IC 110 of FIG. 1 so that stress sensitive region 112 is totally surrounded. A placement region 544 is provided for cavity frame 242. Placement region 544 may be devoid of circuitry in some embodiments, or circuitry that is not stress sensitive may be placed in placement region 544. Region 516 that is outside of placement region 544 may also contain circuitry that is not stress sensitive.

The design rules of the product for the location of sensitive circuits is pre-defined before the circuit design and wafer fabrication. Typically, the stress sensitive circuits which require protection from mold compound stress may be located in a central region of the die.

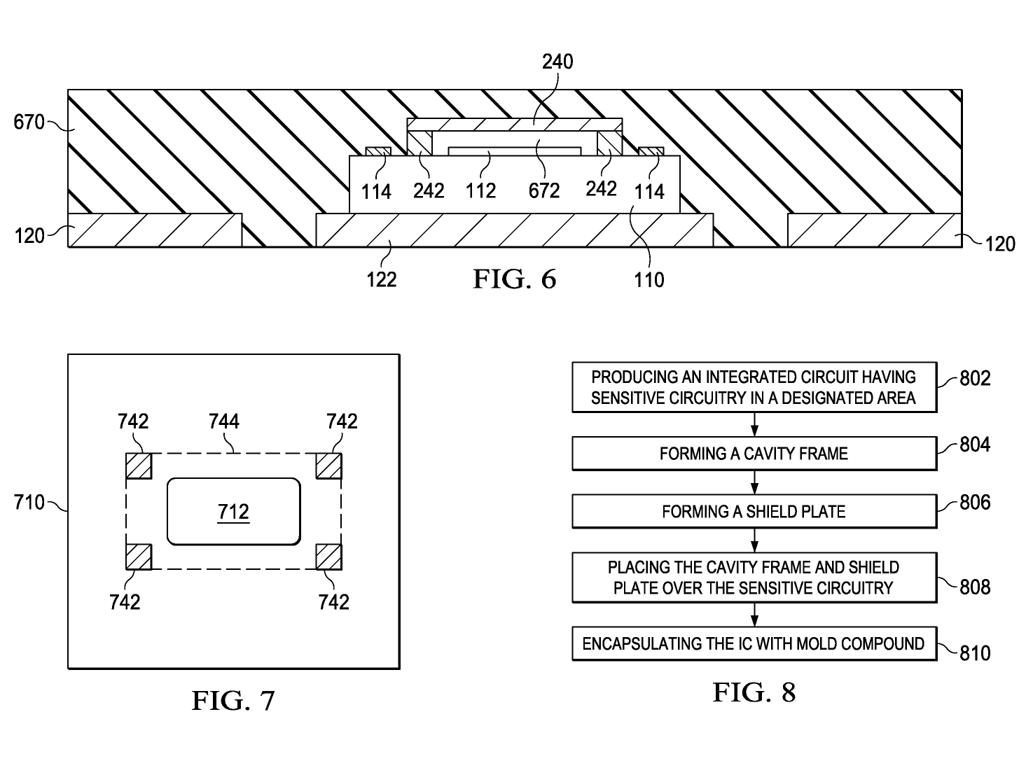

FIG. 6 is an illustration of IC 110 of FIG. 1 after it has been encapsulated. EMC 670 is formed around IC 110 using known or later developed injection molding techniques and completely encapsulates IC 110 to protect it from mechanical and environmental damage. However, as described above, shield plate 240 and cavity frame 242 together prevent any EMC from coming into region 672 and thereby completely eliminate EMC induced stress on sensitive circuit region 112.

In this manner, embodiments of the invention may provide a totally stress free environment for sensitive circuitry by using shield material derived from silicon wafers that have a similar CTE as IC die 110.

There is no requirement to have new tooling to form the cavity frame and shield plate since combination of known laser cutting (programmable) and standard blade saw methods may be used.

Since the silicon cavity frame and silicon shield plate may be made from plain silicon (without any circuits), the cost is negligible since typically one plain wafer (referred to as a dummy wafer or bare silicon) can provide thousands of pieces of the cavity frame and silicon shield plate. The cost of cavity frame and silicon shield plate will be even more insignificant if 300 mm diameter plain silicon is used.

FIG. 7 is an illustration of another embodiment of an IC 710 with a minimized cavity frame 742. In this embodiment, cavity frame 742 is formed by a raised region, such as a hillocks or mesa, at various points in placement region 744. In this example, a cavity frame portion 742 is located at each corner of stress free region 712. A shield plate is then placed over the multiple cavity frame portions 742.

The height of each raised region 742 must be high enough to elevate the stress plate above the sensitive circuitry region but low enough that EMC material cannot squeeze under the open areas between each raised region 742. Typically, filler size in the mold compound may range between 20-80 um in diameter. An average size may be around 55 um. Thus, if the thickness of the gap is kept below approximately 20 um, EMC filler material will not be able to penetrate the opening. Depending on the viscosity of the EMC resin, a thinner gap may be needed to exclude resin flow.

In practice, the raised regions 742 may be formed on IC die 710 by forming a conformal coating over IC 710 and then etching to form raised regions 742. A similar process may also be used to form a solid cavity frame similar to cavity frame 242.

Alternatively, a full cavity frame similar to cavity frame 242 or a partial cavity frame such as portions 742 may be formed on stress plate 240 before dummy wafer 360 is sawn into individual shield plates. In this manner, a one piece shield plate and cavity frame may be formed. A cavity may be formed by etching away a portion of silicon from wafer 360, or by applying a conformal coating and then etching the conformal coating to form a cavity, for example.

Alternatively, silicon epoxy, for example, may be dispensed onto placement region 744 around the stress sensitive circuit area without using a cavity frame. A shield plate may then be placed on the silicon epoxy. This will create a “cavity” space between the silicon shield plate.

FIG. 8 is a flow diagram illustrating provision of stress isolation for stress sensitive circuitry. An integrated circuit is formed 802 using known design and processing techniques. An area of the IC is designated to contain analog or other types of sensitive circuitry that may be sensitive to mechanical stress caused by mold compound that is used to package the IC.

A cavity frame is formed 804 as described in more detail above. The cavity frame may be formed from a dummy wafer as a separate part, or may be formed by depositing a compound, such as silicon epoxy, around the designated area that contains the stress sensitive circuitry. Alternatively, the cavity frame may be formed by applying a conformal coating to the IC and then etching away the conformal coat from the designated area.

A shield plate is formed 806 by sawing or scribing another dummy wafer, as described above in more detail. Alternatively, the shield plate and cavity frame may be formed as one part by etching away a portion of the shield plate to leave a cavity frame around the edge of the shield plate.

The shield plate and cavity frame are placed 808 over the designated area that contains the stress sensitive circuitry. The shield plate and cavity frame may be affixed to the IC using various adhesive materials, such as epoxy, silicon paste, die attach film, etc.

The IC is then encapsulated 810 using a known or later developed molding process. The shield plate and cavity frame prevent mold compound from touch the stress sensitive circuitry.

Various systems may benefit from an embodiment of a stress-free IC package as described herein. For example, temperature sensors may need to have very precision output so that it can be accurately measure the temperature for specific application, such as for an automotive engine without being influenced by ambient temperature changes, such as from different seasons. Another example is a precision amplifier, etc.

### Other Embodiments

While the invention has been described with reference to illustrative embodiments, this description is not intended to be construed in a limiting sense. Various other embodiments of the invention will be apparent to persons skilled in the art upon reference to this description. For example, in the examples described herein, a generally square shape for the stress shield was described. Other embodiments may use a different shape, such as a rectangular shape, for example.

As described herein, the shield plate and the cavity frame may be formed as a single piece, or as two separate pieces. The cavity frame may be a separate piece, or may be formed by deposition and/or etching on the surface of an IC.

In another embodiment, the IC substrate, cavity frame and shield plate may be formed from a material other than silicon, as long as they have a similar coefficient of thermal expansion.

While protection of stress sensitive circuitry was described herein, another embodiment may contain a microelectronic mechanical system (MEMS) in which the movable mechanical parts may be protected by a cavity formed as described herein.

As described herein, a shield plate may be formed from a dummy silicon wafer. Other embodiments may form a shield plate from different materials that have a coefficient of expansion that is similar to the semiconductor substrate that is used in the IC.

While a QFN leadless leadframe was described herein, other embodiments may use other known or later developed leadframe configurations.

Certain terms are used throughout the description and the claims to refer to particular system components. As one skilled in the art will appreciate, components and processes may be referred to by different names and/or may be combined in ways not shown herein without departing from the described functionality. This document does not intend to distinguish between components that differ in name but not function. In the following discussion and in the claims, the terms “including” and “comprising” are used in an open-ended fashion, and thus should be interpreted to mean “including, but not limited to . . . ” Also, the term “couple” and derivatives thereof are intended to mean an indirect, direct, optical, and/or wireless electrical connection. Thus, if a first device couples to a second device, that connection may be through a direct electrical connection, through an indirect electrical connection via other devices and connections, through an optical electrical connection, and/or through a wireless electrical connection.

Although method steps may be presented and described herein in a sequential fashion, one or more of the steps shown and described may be omitted, repeated, performed concurrently, and/or performed in a different order than the order shown in the figures and/or described herein. Accordingly, embodiments of the invention should not be considered limited to the specific ordering of steps shown in the figures and/or described herein.

It is therefore contemplated that the appended claims will cover any such modifications of the embodiments as fall within the true scope and spirit of the invention.

What is claimed is:

1. A packaged semiconductor device comprising:
a semiconductor substrate with circuitry formed thereon;
a shield plate mounted over a designated region of the semiconductor substrate;
a separator between the semiconductor substrate and the shield plate, such that the shield plate is separated from the designated region of the substrate by a distance; and
mold compound covering the semiconductor substrate and the shield plate, wherein the shield plate and the separator prevent mold compound from contacting the designated region of the semiconductor substrate.

2. The semiconductor device of claim 1, wherein the semiconductor substrate includes stress sensitive precision circuit located in the designated region of the semiconductor substrate.

3. The semiconductor device of claim 1, wherein the semiconductor substrate includes a microelectronic mechanical system located within the designated region of the semiconductor substrate.

4. The semiconductor device of claim 1, wherein the semiconductor substrate and the shield plate are silicon and have a similar coefficient of thermal expansion.

5. The semiconductor device of claim 1, wherein the separator and shield plate are formed as a single part.

6. The semiconductor device of claim 1, wherein the separator is formed on the semiconductor substrate.

7. The semiconductor device of claim 1, wherein the shield plate is coupled to the semiconductor substrate using epoxy or a die attach film.

8. A method for protecting sensitive circuitry on an integrated circuit, the method comprising:
forming an integrated circuit having the sensitive circuitry located in a designated portion of the integrated circuit (IC) substrate;
forming a cavity frame;
forming a shield plate;
placing the shield plate and cavity frame over the designated portion of the IC substrate; and
encapsulating the IC substrate using a mold material, wherein the shield plate and cavity frame prevent the mold material from touching the sensitive circuitry.

9. The method of claim 8, wherein the cavity frame and shield plate are formed as a single piece.

10. The method of claim 8, wherein the cavity frame is formed by laser cutting a silicon wafer.

11. The method of claim 8, wherein the shield plate is formed by dicing a silicon wafer.

12. The method of claim 8, wherein the cavity frame is formed by depositing a material on the IC substrate around the sensitive circuitry.

13. The method of claim 8, wherein the cavity frame is formed by etching away a region of a conformal coating over the designated portion of the IC substrate.
